(19) United States
(12) Patent Application Publication
(10) Pub. No.: US 2003/0222296 A1
(43) Pub. Date: Dec. 4, 2003

(54) Method of forming a capacitor using a high K dielectric material

(75) Inventors: Ajay Kumar, Sunnyvale, CA (US); Padmapani Nallan, San Jose, CA (US); Anisul H. Khan, Santa Clara, CA (US); Ralph Kerns, San Carlos, CA (US); Virinder S. Grewal, Santa Clara, CA (US)

Correspondence Address: Moser Patterson & Sheridan LLP, 595 Shrewsbury Ave, Suite 100, Shrewsbury, NJ, 07702, US

(73) Assignee: Applied Materials, Inc.

(21) Appl. No.: 10/163,019

(22) Filed: Jun. 4, 2002

(51) Int. Cl. H01L 27/108

(52) U.S. Cl. 257/301

(57) ABSTRACT

A method of forming a capacitor using a high dielectric constant material.

### BACKGROUND OF THE INVENTION

1. Field of Invention

The present invention relates generally to a method of process integration during fabrication of integrated circuit components on the semiconductor substrates. More specifically, the invention relates to a method of forming a capacitor using materials with a high dielectric constant.

2. Description of the Background Art

Integrated circuits have evolved into complex devices that can include millions of components (e. g., transistors, capacitors, and resistors) on a single chip. The evolution of chip designs continually requires faster circuitry, greater circuit densities and necessitates a reduction in the dimensions of the integrated circuit components and use of materials that improve electrical performance of such components. One group of such materials is the materials with high dielectric constant.

Dynamic random access memory (DRAM) integrated circuits are commonly used for storing data in a digital computer. DRAM generally includes a large number of storage units called cells. The cells are arranged as a planar array of horizontal rows and vertical columns. Horizontal lines connected to all the cells in a row are called word lines. Vertical lines connected to all the cells in a column are called bit lines. The bit lines and the word lines are used to read and write data to the individual cells of the array. In DRAM each memory cell comprises a transistor coupled to a sub-micron sized deep trench capacitor. Data (e.g., digital information) is stored in each cell as a charge on the capacitor located therein. To facilitate construction of larger DRAM, smaller memory cells with smaller capacitor structures are needed. One limitation to reducing the size of memory cells is that the capacitors must have sufficient capacitance for reliable charge storage.

A trench capacitor is formed in a trench defined vertically into a surface of a silicon substrate. An insulator comprises a dielectric material that is formed conformably along the sidewalls of the trench. A doped polysilicon layer (also referred to herein as polysilicon) is formed over the insulating layer so as to fill the trench. In the trench capacitor, the doped silicon substrate acts as a first electrode (also referred to herein as a bottom electrode) and the polysilicon acts as a buried second electrode. A metal layer (also referred to herein as a conductive plug) is formed to provide an electrical connection for the polysilicon to the lines of DRAM.

Capacitance of a trench capacitor increases as a depth of the trench and a dielectric constant of the insulator increase. Similarly, the capacitance increases with a decrease in a thickness of the insulator. Therefore, it is desirable to form the capacitors in trenches that have a high aspect ratio. The term aspect ratio as used herein refers to a height of the trench divided by its width. Capacitors with the aspect ratio greater than 10 are referred to herein as deep trench capacitors. Further, to achieve high capacitance in a small trench, it is desirable to use a thinner insulator and form the insulator of a dielectric material with a high dielectric constant.

In a DRAM capacitor, the insulator is typically a composite stack of a silicon dioxide layer and one of the Al₂O₃, ZrO₂, BST, PZT, ZrSiO₂, HFSiO₂, or TaO₂ layers. Thickness of the composite stack in DRAM capacitors is generally less than 25 nm. However, with such a thin insulator, electrons can propagate from the polysilicon electrode through the insulator, causing an electrical breakdown and potentially rendering the capacitor inoperable. Formation of the polysilicon electrodes includes an annealing process performed at temperatures between 1000 to 1150 degrees Celsius. Such high temperatures can adversely affect electrical performance of the insulator. One very stable dielectric material having a high dielectric constant is hafnium-oxide. However, hafnium-oxide is such a stable material that it is difficult to integrate into a fabrication process of deep trench capacitors for DRAM.

Therefore, a need exists in the art for a method of forming capacitors using dielectric materials with a high dielectric constant.

### SUMMARY OF INVENTION

The disadvantages associated with the prior art are overcome by a method of forming a capacitor using a dielectric material having a high dielectric constant. One such material is hafnium dioxide. The method comprises depositing the dielectric material upon a substrate, depositing a conductive material upon the dielectric material, removing a portion of the conductive material to expose a portion of the dielectric material, and etching the dielectric material by exposing the dielectric material to a plasma comprising a halogen containing gas and a reducing gas while maintaining the substrate at a temperature of at least 100 degrees Celsius.

### BRIEF DESCRIPTION OF DRAWINGS

The teachings of the present invention can be readily understood by considering the following detailed description in conjunction with the accompanying drawings, in which:

FIG. 1 depicts a flow diagram of an example of the inventive method; and

FIGS. 2a-2h depict a sequence of schematic cross-sectional views of a substrate having a deep trench capacitor being formed in accordance with an example of the present invention.

To facilitate understanding, identical reference numerals have been used, where possible, to designate identical element that are common to the figures.

### DETAILED DESCRIPTION

The present invention is a method of forming a capacitor using a dielectric material with a high dielectric constant. Such capacitors find use in the fabrication of sub-100 nm deep trench DRAM capacitors. Herein dielectric materials with a dielertric constant greater than 4 are referred to as the high K materials. Specifically, in one embodiment of the present invention, hafnium-dioxide (HfO₂) is used as an insulator in the DRAM capacitors. Hafnium-dioxide is a material having a dielectric constant greater than 20 and stable at the temperatures between 1000 to 1150 degrees Celsius.

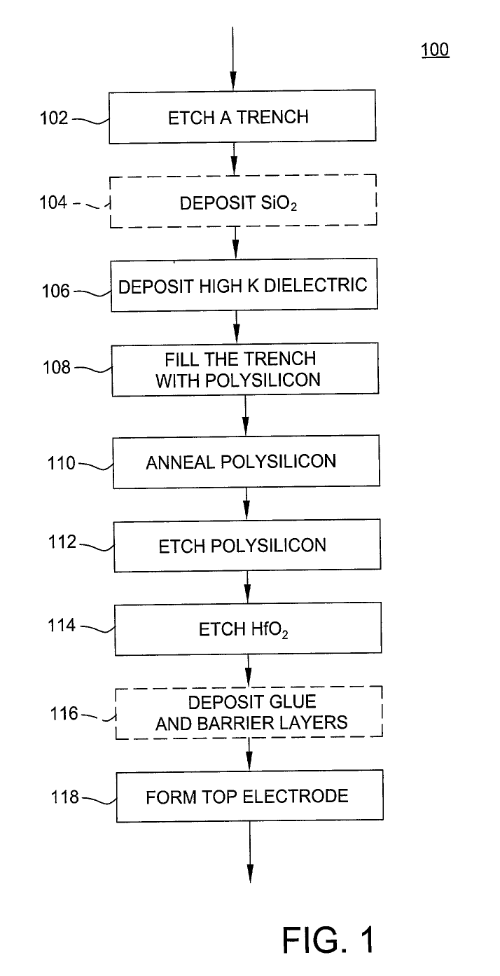

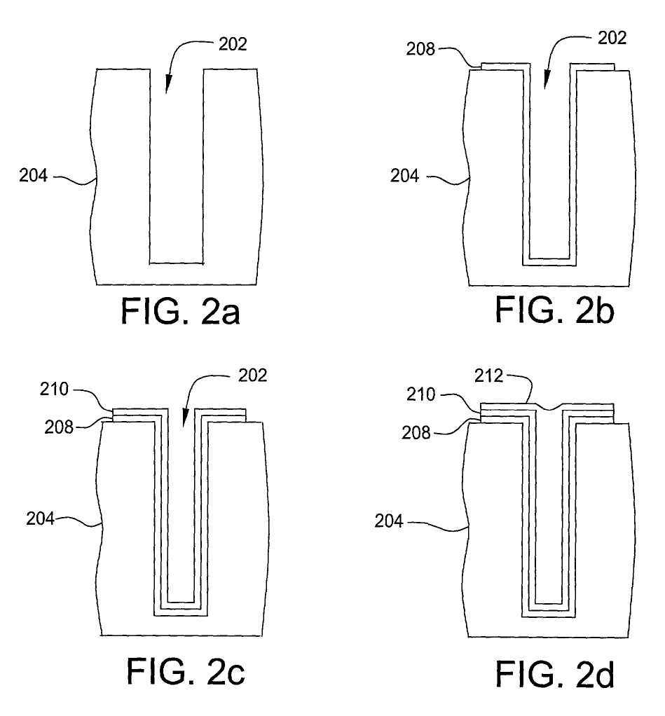

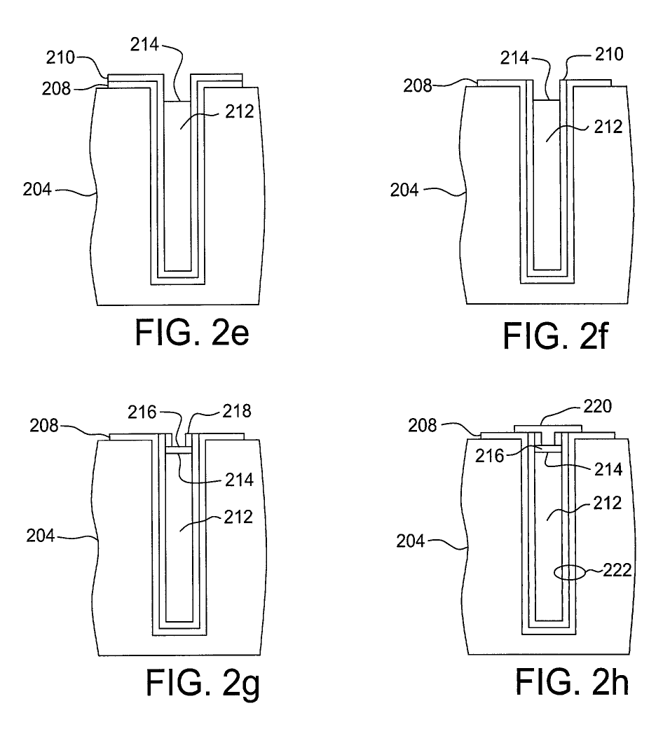

FIG. 1 depicts a flow diagram of one embodiment of the method of forming a capacitor using a high K dielectric material as a sequence 100. The sequence 100 comprises steps 102, 104, 106, 108, 110, 112, 114, 116, and 118. FIGS. 2a-2h depict a sequence of schematic cross-sectional views of a substrate (also referred to herein as a wafer) having a deep trench capacitor being formed therein using the sequence 100. The cross-sectional views relate to individual process steps used to form a capacitive structure. Sub-processes and lithographic routines such as application, exposure, development and removal of photoresist, and the like are not shown in FIGS. 1 and 2a-2h. The images in FIGS. 2a-2i are not depicted to scale and are simplified for illustrative purposes.

At step 102, a trench 202 is etched in a semiconductor layer 204 (generally, a silicon layer) on a wafer (FIG. 2a). At an optional step 104, a conformal layer 208 of silicon dioxide (SiO₂) is formed in the trench 202 (FIG. 2b). The SiO₂ layer 208 may be formed using a thermal oxidation process that is applied prior to deposition of the high K dielectric material.

At step 106, a layer 210 of a high K dielectric material is deposited (FIG. 2c). The high K dielectric layer 210 is deposited using a chemical vapor deposition (CVD) process or, alternatively, an atomic layer deposition (ALD) process. The layer of SiO₂ of step 104 may be inherently formed when oxygen from tare high K dielectric material contacts the silicon of the wafer. As such, this layer nay be a thin, monolayer of SiO₂. At step 108, the trench 202 is filled with a conductive material, such as doped polysilicon 212 or a metal, to form an in-trench electrode (FIG. 2d). The conductive material is deposited using a CVD or PVD process.

At step 110, if the conductive material is polysilicon, the polysilicon 212 is annealed led using a rapid thermal annealing process at a temperature of between 1000 to 1150 degrees Celsius. The polysilicon 212 can be annealed using one of several different routines. Specifically, the polysilicon 212 can be annealed at one or more constant temperatures between 1000 to 1150 degrees Celsius. Alternatively, the polysilicon is annealed at a temperature that varies between 1000 to 1150 degrees Celsius, or annealed at fixed temperatures that are stepwise increased of 1020, 1050, and 1120 degrees Celsius. Duration of the annealing is generally between 50 to 350 seconds.

At step 112, the polysilicon 212 is partially removed by an etch process or a combination of the chemical-mechanical polishing (CMP) and etch processes to form a contact surface 214 (FIG. 2e). At step 114, the high K dielectric layer 210 is etched back from a top of the trench 202 (FIG. 2f). The SiO₂ layer, if present, may bar used as an etch stop. Alternatively, the etch back can continue until the layer 210 is removed from the top and sidewalls of the trench 202 down up to the contact surface 214.

At steps 116 and 118, a conductive plug 220 is formed using one of several conventional metallization techniques, e.g., cyclical deposition techniques that include CVD or physical vapor deposition (PVD) processes, an electroplating process, and the like. At optional step 116, a glue layer 216 and/or a barrier layer 218 are deposited (FIG. 2g). At step 118, a metal layer is deposited to form a conductive plug 220 (FIG. 2h). The conductive plug 220 is generally made from aluminum (Al), copper (Cu), tantalum (Ta) or tungsten (W) based material with intermediate glue and barrier layers to form a conductive path to the polysilicon 212. 1he conductive plug 220 can be deposited using conventional PVD, CVD, or electroplating techniques or a combination of such techniques. The glue layer 216 improves an interface between the conductive plug 220 and the polysilicon 212. The barrier layer 218 minimizes the diffusion of a metal into an insulating material. Diffusion of the metal into the insulating material is undesirable because such diffusion can make the capacitive structure defective. A capacitor 222 is formed by the semiconductor layer 204 operating as a first electrode, the high K dielectric layer 210 operating as an insulator, and the polysilicon layer 212 operating as a second electrode.

The etch process of step 114 can be reduced to practice in an etch reactor such as the Decoupled Plasma Source (DPS or DPS-II) etch reactor of semiconductor wafer processing system Centura®, available from Applied Materials, Inc. of Santa Clara, California. In general, the etch reactor uses an inductive source power of about 200-2500 W for plasma generation and applies a cathode bias power of about 5-100 W to a wafer support pedestal. The DPS or DSP-II reactor maintains the pedestal within a temperature range of about 100 to 500 degrees Celsius. In one embodiment, a wafer is maintained at a temperature of 350 degrees Celsius during etch. A plasma is generated from a gas (or mixture) comprising gases containing a halogen gas (chlorine (Cl₂), hydrogen chloride (HCI), and the like) and a reducing gas (carbon monoxide (CO) and the like). The plasma is used to etch a high K material. The high K materials include HfO₂, ZrO₂, Al₂O₃, barium strontium titanate (BST), lead zirconate titanate (PZT), ZrSiO₂, HfSiO₂, HfSiON, TaO₂, and the like. The exact stoichiometry is not critical and may vary from the ratios given in the formulas. The composition of the materials may include dopants such as nitrogen or other materials that improve the properties of the dielectric materials. The type of halogen gas is selected to best remove the metal from the dielectric layer and the type of reducing gas is selected to best remove the oxygen from the dielectric layer. Such an etch process is disclosed in U.S. patent application No. 10/092,795, filed Mar. 6, 2002 (Attorney Docket No. 7017), which is incorporated herein by reference in its entirety.

Employing hafnium-oxide, the capacitive structures can be formed using the sequence 100 in trenches 202 having a width between 10 and 300 nm and an aspect ratio between 10 and 100. Specifically, the trenches can have a width between 50 and 120 nm and an aspect ratio between 50 and 60. The layer 210 of HfO₂ can have thickness of 10 nm or less. Specifically, the HfO₂ layer having thickness between 1 to 4 nm can be used in the DRAM capacitors. The HfO₂ layer can be deposited directly on the surface of the trench. The oxygen in hafnium dioxide may diffuse into the silicon of the substrate to form a thin layer (monolayer) of silicon dioxide. Alternatively, the HfO₂ layer can be deposited on the conformal layer 208 of SiO₂ that may be formed during step 104.

The invention can be practiced, in an example of hafnium-oxide, by supplying to the DPS or DPS-11 reactor a combination of about 40 sccm of chlorine gas and about 40 sccm of carbon monoxide gas while maintaining a total chamber pressure of about 4 mTorr. The gas mixture is supplied to the reaction chamber wherein the plasma is formed and a hafnium-oxide layer is etched. In one embodiment of the invention, an etch gas (or mixture) comprising a halogen gas such as Cl₂ and a reducing gas such as CO is used for etching a HfO₂ layer. In one example, the gas flow rates are in the range 20-300 sccm Cl₂ and about 2-200 sccm CO (i.e., a Cl₂/CO flow ratio is (0.1-1):(1-0.1)), with a total pressure in the range of 2-100 mTorr. The etch time during step 114 can be terminated upon a certain optical emission occurring, upon a particular duration occurring, or upon some other indicator determining that the unmasked hafnium-oxide has been removed. Alternatively, the thin SiO₂ layer 208 can be used as an etch stop layer. It should be understood, however, that a use of an etch system, different from the DPS or DPS-II, may necessitate different process parameters and ranges.

The invention has been discussed using a trench capacitor as one example of a capacitor that can be formed using the method of the present invention. Other forms of capacitors, such as stacked capacitors, may be formed using a high K dielectric that is etched in the manner described above. As such, the stacked capacitor may be formed in a smaller area than previously available using low K dielectric materials (i.e., materials with dielectric constants less than about four.

The invention may be practiced in other semiconductor structures and devices wherein the processing parameters may be adjusted to achieve acceptable characteristics by those skilled in the arts by utilizing the teachings disclosed herein without departing from the spirit of the invention.

what is claimed is:

1. A method of forming a capacitor using a dielectric material having a dielectric constant that is greater than 4, comprising:
depositing the dielectric material upon a substrate;
depositing a conductive material upon the dielectric material;
removing a portion of the conductive material to expose a portion of the dielectric material; and
etching the dielectric material by exposing the dielectric material to a plasma comprising a halogen containing gas and a reducing gas while maintaining the substrate at a temperature of at least 100 degrees Celsius.

2. The method of claim 1 wherein the conductive material is polysilicon.

3. The method of claim 1 further comprising forming a trench in which the dielectric material and the conductive material are deposited.

4. The method of claim 3 wherein the step of depositing a conductive material comprises filling the trench by depositing polysilicon in the trench; and annealing the polysilicon.

5. The method of claim 3 wherein the trench has a width between 10 and 300 nm.

6. The method of claim 3 wherein the trench has a width between 50 and 120 nm.

7. The method of claim 3 wherein the trench has a ratio of a depth to the width between 10 and 100.

8. The method of claim 3 wherein the trench has a ratio of a depth to the width between 50 and 60.

9. The method of claim 1 wherein the layer of the dielectric material has a thickness less than 10 nm.

10. The method of claim 1 wherein the layer of the dielectric material has a thickness between 1 and 4 nm.

11. The method of claim 1 wherein the dielectric material is at least one of HfO₂, ZrO₂, Al₂O₃, BST, PZT, ZrSiO₂, HfSiO₂, HfSiON and TaO₂

12. The method of claim 1 wherein the dielectric material is HfO₂.

13. The method of claim 1 wherein the halogen containing gas comprises a chlorine containing gas.

14. The method of claim 13 wherein said chlorine containing gas is Cl₂.

15. The method of claim 1 wherein the reducing gas comprises carbon monoxide.

16. The method of claim 1 wherein halogen containing gas comprises chlorine and the reducing gas comprises carbon monoxide.

17. The method of claim 4 wherein an electrode is formed on a contact surface of the polysilicon.

18. The method of claim 1 wherein, during said etching step, the substrate is maintained at a temperature of 350 degrees Celsius.

19. The method of claim 1 wherein the dielectric material comprises hafnium.

20. The method of claim 1 wherein the capacitor is a stacked capacitor.

21. A method of forming a trench capacitor comprising:
forming a trench in a substrate;
depositing hafnium-containing material into the trench;
depositing a conductive material upon the hafnium-containing material;
removing a portion of the conductive material to expose a portion of the hafnium-containing material;
etching the hafnium-containing material using a plasma comprising a chlorine-containing gas and carbon monoxide while maintaining the substrate at a temperature of at least 100 degrees Celsius.

22. The method of claim 21 wherein said conductive material is polysilicon and the method further comprises annealing the polysilicon.

23. The method of claim 21 wherein the trench has a width between 10 and 300 nm.

24. The method of claim 21 wherein the trench has a width between 50 and 120 nm.

25. The method of claim 21 wherein the trench has a ratio of a depth to the width between 10 and 100.

26. The method of claim 21 wherein the trench has a ratio of a depth to the width between 50 and 60.

27. The method of claim 21 wherein the hafnium-containing material is a layer having a thickness of less than 10 nm.

28. The method of claim 21 wherein the hafnium-containing material is a layer having a thickness between 1 and 4 nm.
